(19) United States
(12) Patent Application Publication
(10) Pub. No.: US 2005/0237556 A1
(43) Pub. Date: Oct. 27, 2005

(54) Printer input device having intelligent and non-intelligent modes

(76) Inventor: Rex D. Watkins, Franklin, OH (US)

Correspondence Address: McAndrews, Held & Malloy, Ltd., 34th Floor, 500 West Madison Street, Chicago, IL, 60661, US

(21) Appl. No.: 10/818,725

(22) Filed: Apr. 6, 2004

(51) Int. Cl. G06F 3/12; G06F 3/06; G06F 3/00; G06F 13/10; G06F 1/16; G06K 15/02; G06K 7/10; G06K 9/22; H05K 5/00

(52) U.S. Cl. 358/1.13; 710/72; 710/14; 361/680; 235/145 R; 235/462.01; 235/462.45

(57) ABSTRACT

An input device for a barcode label/tag printer is operable in a first or non-intelligent mode wherein the input device passes data, representing user actuable keys, to the printer without processing the data. The input device is also selectably operable in a second or intelligent mode wherein the input device operates in accordance with an application program to manipulate data before sending it to the printer.

### CROSS-REFERENCE TO RELATED APPLICATIONS

This application is related to U.S. application Ser. No. 10/193,557 filed Jul. 11, 2002 assigned to the assignee of the present invention.

### STATEMENT REGARDING FEDERALLY SPONSORED RESEARCH OR DEVELOPMENT

N/A

### FIELD OF THE INVENTION

The present invention is directed to an input device for a printer such as a keyboard and more particularly to such an input device having two modes of operation, a first mode in which the input device operates in a conventional manner, e.g. a standard keyboard having no data processing capabilities, and a second mode in which the input device operates in accordance with an application program to form, for example, an intelligent keyboard capable of data collection and/or data manipulation.

### BACKGROUND OF THE INVENTION

Label/tag printers are known that include an application program stored in a programmable memory and an interpreter for processing all data input to the printer in accordance with the application program as shown in U.S. Pat. No. 5,483,624. These printers can manipulate received data in accordance with the application program but they are not operable to print without an application program. Other label/tag printers are known that receive data in a predetermined format for printing; however, these printers cannot manipulate the received data and can only print data if it is received in the predetermined format. Another known printer as disclosed in Ser. No. 10/193,557 filed Jul. 11, 2002 and assigned to the assignee of the present invention, includes an interpreter and a memory for storing an application program where the interpreter can be enabled or disabled to allow the printer to operate to print with or without an application program.

Many of the printers as described above do not include a keyboard or the like for entering data to be printed. Instead, these printers typically receive data transmitted from a host computer or the like that is coupled to the printer via an RS232 port or that communicates with the printer via radio frequency communications. Often, it is desirable to allow an operator of the printer to enter data to be printed right at the site of the printer. However, different input devices are required for printers having different capabilities.

### BRIEF SUMMARY OF THE INVENTION

In accordance with the present invention, the disadvantages of prior input devices for printers have been overcome. The input device of the present invention includes two modes, a first mode for operating the input device in a conventional manner, for example, as a standard keyboard with no data processing capabilities and a second mode for operating the input device in accordance with an application program to provide, for example, an intelligent keyboard that is capable of data manipulation and/or data collection.

More particularly, the input device for a printer in accordance with the present invention includes a housing with a number of keys on a surface of the housing and having a display. The input device also includes at least one communication interface for receiving data and for transmitting data to a printer. The input device has at least one memory for storing an application program that includes a sequence of commands. A memory also stores routines to control the operation of the input device without an application program and a number of routines each of which correspond to a command that can be included in an application program. A processor operates the input device in a first mode according to the routines that control the operation of the input device without an application program and the processor operates the input device in a second mode according to a stored application program wherein the processor in the second mode executes the routines corresponding to the commands in the application program.

In accordance with one embodiment of the present invention, the processor is responsive to a command while the input device is in a second mode to change the mode to the first mode. Similarly, the processor may be responsive to a command while the device is in the first mode to change to the second mode wherein this command may represent the enablement of a stored application program, or the receipt of an application program or the command may merely be the presence of an application program stored in memory.

In accordance with another feature of the present invention, the input device when operating in the first mode is controlled at least in part by inputs received from a printer and wherein the input device, when operating in the second mode, controls at least in part an operation of the printer. For example, the input device when operating in the first mode can receive inputs from the printer to cause the display of the input device to depict the information received from the printer. The displayed information may provide, for example, a prompt to a user to enter data and wherein the input device passes data entered for example, via actuation of one or more keys, to the printer. In the second mode, the input device may control a print operation for example by transmitting a print command to the printer and a data packet or stream in a particular printer control language format that is recognizable by the printer.

The input device of the present invention can thus be used with an intelligent printer that is capable of manipulating data itself or the input device can be used with a non-intelligent printer, wherein the input device provides data manipulation capabilities necessary to provide print commands and data packets in a format understandable by the non-intelligent printer. These and other advantages and novel features of the present invention, as well as details of an illustrated embodiment thereof, will be more fully understood from the following description and drawings.

### BRIEF DESCRIPTION OF THE SEVERAL VIEWS OF THE DRAWINGS

FIG. 1 is a perspective view of an input device in accordance with the present invention;

FIG. 2 is a top view of the input device of FIG. 1;

FIG. 3 is a block diagram illustrating the input device of FIG. 1 in communication with a barcode label printer and a barcode scanner;

FIG. 4 is a flow chart illustrating a main routine of the input device of FIG. 1;

FIG. 5 is a flow chart illustrating a first mode of the input device of FIG. 1;

FIG. 6 is a flow chart illustrating a second mode of the input device of FIG. 1; and

FIGS. 7A-C form a flow chart illustrating an operation of the printer of FIG. 3 communicating with the input device of the present invention.

### DETAILED DESCRIPTION OF THE INVENTION

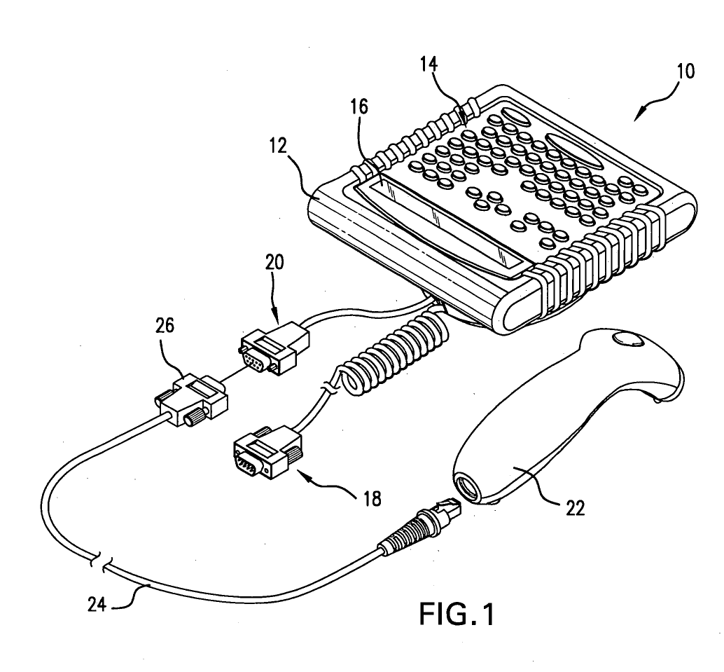

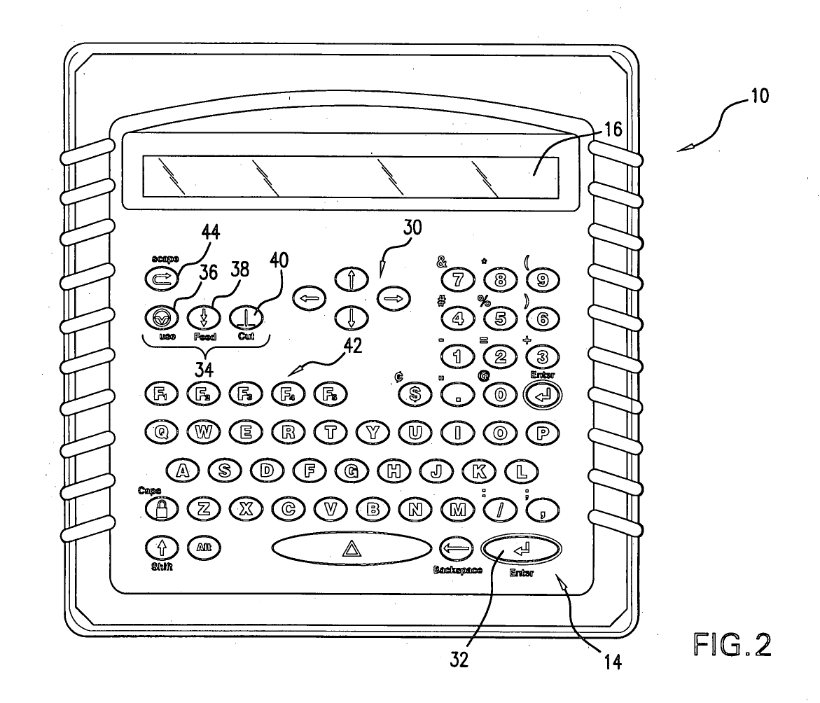

The input device 10 of the present invention, as shown in FIG. 1, includes a housing 12 with a number of keys 14 disposed on a surface of the housing 12. The input device also includes a display 16 which may be a LCD having a single display line or, preferably multiple display lines. Although as shown, the keys 14 are separate from the display 16, an integrated key and display device may be utilized. For example, a touch panel display may be utilized to depict keys on the display wherein the keys are actuated by a touch on the display screen. The input device 10 also includes a communication interface to allow the input device to receive information from and to transmit information to a printer 28. In the embodiment shown in FIG. 1, the communication interface is formed of a communication port 18. In a preferred embodiment, the communication port 18 also provides DC power from the printer to the input device 10 to power the input device. In a preferred embodiment, the input device also includes a second communication port 20 for connection to a barcode scanner 22 via a cable 24 and a communication port 26 that mates with the communication port 20. The barcode scanner 22 senses a barcode and provides digital data to the input device 10 via the mating communication ports 26 and 20. The communication port 20, in a preferred embodiment also provides DC power received from the printer to the barcode scanner 22 to power the scanner.

In a preferred embodiment, the input device 10 includes alphanumeric keys as well as algebraic keys. The input device also includes cursor control keys 30 to move a cursor on the display 16 up and down as well as left and right so that displayed information can be selected utilizing the cursor keys 30 and an enter key 32. In a preferred embodiment, the input device 10 also includes one or more printer control keys 34. Each of the printer control keys when actuated generates a command that is sent by the input device 10 to the printer where the printer control command from the input device 10 controls an operation of the printer. For example, a pause key 36 when actuated will cause the input device 10 to generate a digital pause command which, when sent to the printer, will cause the printer to pause its operation. A feed key 38 when actuated generates a feed command for a printer to cause the printer to advance the printing stock through the printer. The printing stock may be a strip or roll of labels, a roll of tags, a roll of paper, or the like on which the printer prints information. A cut control key 40 when actuated generates a cut command for a printer to cause the printer to cut the printing stock, for example tags to separate one tag from another. In a preferred embodiment, the keys 14 of the input device include five programmable function keys F1, F2, F3, F4 and F5 42. Various functions can be assigned to the function keys via an application program such that the function performed in response to the actuation of a particular function key is programmable. The key 14 of the input device also include an escape key 44 to escape a current operation of the input device 10.

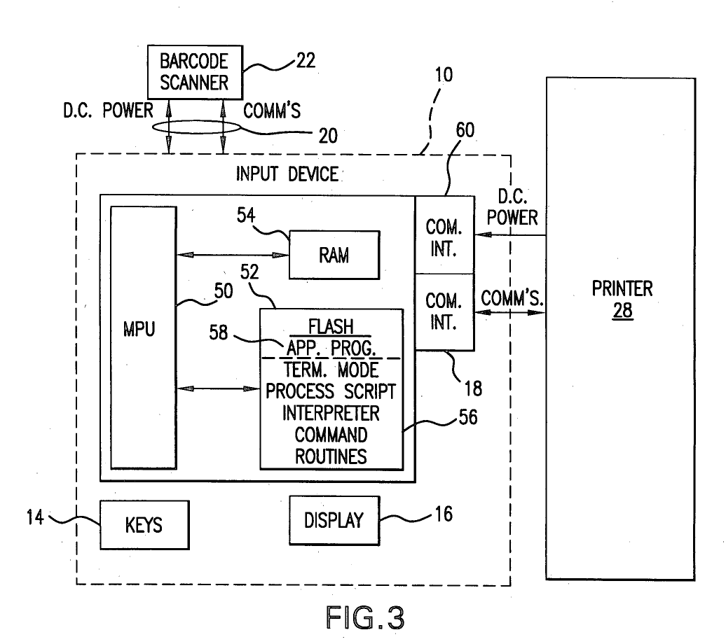

The input device 10 as shown in FIG. 3 includes a microprocessor 50 operating in accordance with firmware/software stored in a flash memory 52 and data stored in a RAM 24. The flash memory 52 includes an area 56 to which access is preferably restricted, the area 56 of the flash memory 52 storing the firmware of the input device 10. An unrestricted area 58 of the flash memory 52 stores an application program that can be downloaded into the printer 10 via a communication interface 60. The communication interface 60 may be an RS232 port or a radio frequency interface if desired for communicating with a host computer such as a P.C. or the like. The area 56 of the flash memory 52 may be restricted such that a special loader is required to write to the area 56 of the flash memory. As such, the routines stored in the area 56 of the memory 52 are programmable and can change or updated, however, the routines stored therein are not meant to be changed by a user of the input device. It should be appreciated that other methods of restricting or limiting access to the flash memory area 56 may be employed other than a special loader. In an alternative embodiment, the application program may be stored in a RAM 54 which may be volatile or non-volatile such as a battery backed RAM as desired. Further, if the application program is stored in the area 58 of the flash memory 52, the application program may be loaded by a routine stored in the restricted area 56 of the memory 52 into the RAM 54 so that the application program is actually run or executed out of the RAM 54 as opposed to the flash memory. The application program is stored in either a RAM or an unrestricted area 58 of the flash memory 52 so that the application program can be easily updated by a user. It is noted that the firmware of the input device 10 may also be stored in a type of ROM other than a flash memory, i.e. EEPROM, such as an EPROM if desired.

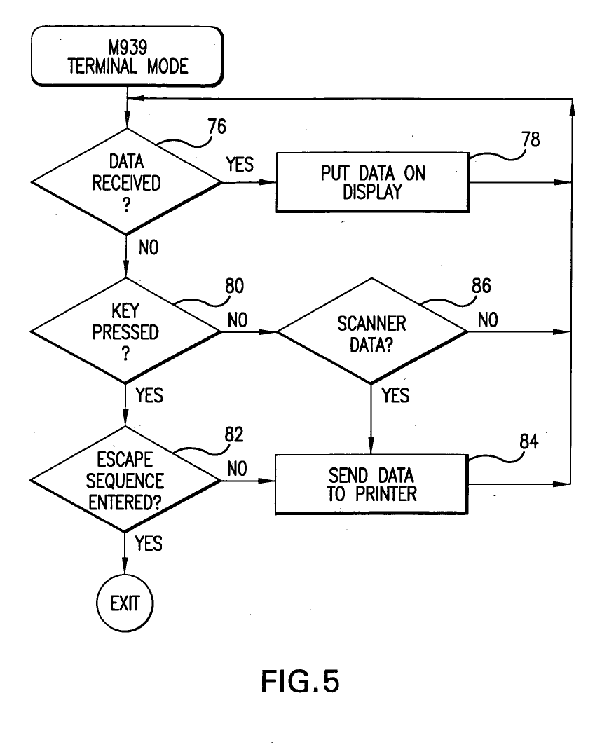

The application program is formed of a sequence of high level commands. These commands may be commands of a programming language such as the Plus programming language or ADK programming language used by Monarch Marking Systems, Inc. and/or Paxar Americas, Inc. However, the application program can use other languages such as BASIC commands or the like. The application program is preferably written in a high level programming language so that it is easy for a user to write an application program that can be downloaded into the input device 10 from a standard personal computer. The firmware of the input device stored in the area 56 of the flash memory 52 includes command routines wherein each command routine is associated with and corresponds to a command that can be used in an application program of the device 10. Specifically, for each command that can be used in an application program, there is a corresponding command routine that is selected and executed by the processor 50 when the application program is executed. An application program interpreter is also stored in the area 56 of the memory 52. The microprocessor 50 operates in accordance with the interpreter to execute command routines that correspond to the commands set forth in the application program. An example of a suitable application program interpreter is depicted in U.S. Pat. No. 5,483,624 assigned to the assignee of the present invention and incorporated herein by reference. This patent also depicts commands that can be used to form an application program as well as the command routines corresponding to the commands. In a preferred embodiment, the commands and command routines are as shown in U.S. Pat. No. 5,483,624 which can be used for data collection, i.e. for gathering previously non-associated data together in a file, table or an array and for manipulating data to associate previously non-associated data. The commands and command routines are preferably flexible enough so that an application program can be used to generate printer control language commands and/or data packets that can be understood by the printer 28 for which the input device is used. Various printer control languages are known and used in the industry including a Monarch Printer Control Language (MPCL), a Zebra Printer Control Language (ZPCL), etc. Each printer control language has an associated format for printer data so that a printer 28 operating in accordance with a particular printer control language can understand the data received in the format of its printer control language. The area 56 of the memory 52 also stores routines according to which the microprocessor 50 operates to control the operation of the input device 10 without an application program 58. An example of such a routine is depicted in FIG. 5.

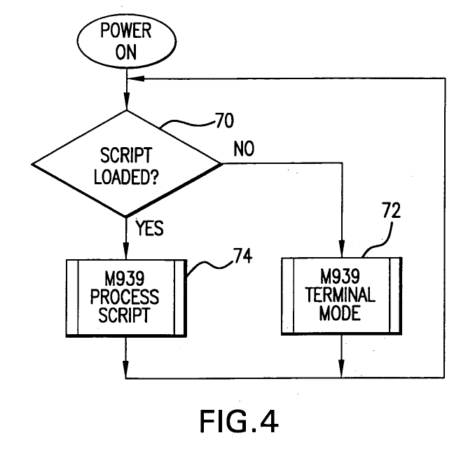

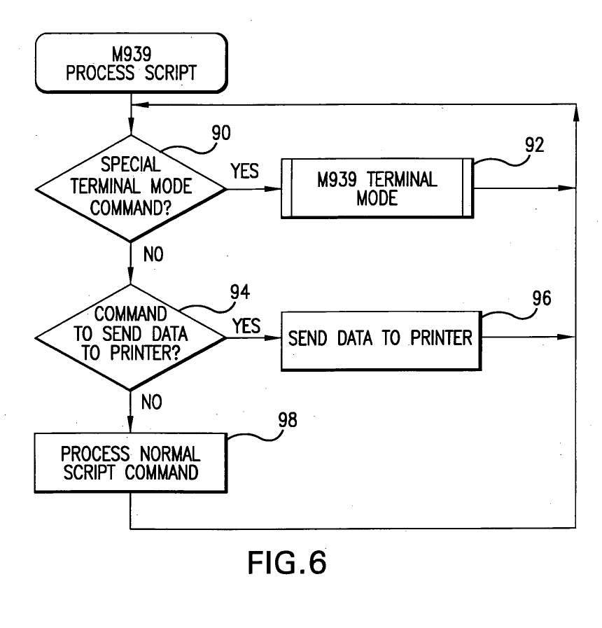

As shown in FIG. 4, upon powering up the input device 10, the microprocessor 50 at a block 70 determines whether a script, which is another name for an application program, has been loaded into a memory 54 or 58 or enabled. If no application program is loaded or enabled for operation, the microprocessor 50 proceeds from block 70 to block 72 to implement the routine depicted in FIG. 5 to operate the input device in a first mode without the use of an application program. If the microprocessor 50 determines at block 70 that an application program has been loaded into a memory of the printer and the application program is enabled, i.e. operational, the microprocessor proceeds from block 70 to block 74. At block 74, the microprocessor 50 implements the routine depicted in FIG. 6 to operate the input device in a second mode in accordance with an application program.

The processor 50 operates the input device in a first mode, also referred to as a terminal mode, without an application program as depicted in FIG. 5. In the first mode, the microprocessor 50 at block 76 determines whether an data has been received via the communication interface 18 from the printer 28. If so, the microprocessor 50 at block 78 controls the display 16 to depict information representing the data received from the printer 28. In this way, if the printer 28 is an intelligent printer, the printer 28 can control an operation of the input device 10 such as controlling the information depicted on the display 16. For example, the printer 28 may send data to the input device 10 representing a prompt for information that is depicted on the display 16 so as to prompt a user to enter a particular type of data using the keys 14 and/or the barcode scanner 22. If the microprocessor 50 determines at block 76 that no data has been received via the communication interface 18 from the printer, the microprocessor 50 proceeds to block 80 to determine whether one of the keys 14 has been pressed. If a key 14 has been pressed, the microprocessor 50 proceeds to block 82 to determine whether an escape sequence has been generated by actuation of the Alt and F1 keys and if so, the microprocessor 50 exits the routine depicted in FIG. 5. If the microprocessor 50 determines that keys other than those generating the escape sequence have been actuated, the microprocessor 50 proceeds to block 84 to send data representing the actuated key to the printer 28 via the communication interface 18. If the microprocessor 50 determines at block 80 that a key has not been pressed, the microprocessor 50 determines at block 86 whether the input device has received any barcode data from the scanner 22 via the communication interface 20. If so, the microprocessor 50 proceeds from block 86 to block 84 to send data representing the sensed barcode to the printer 28.

The input device 10 operates in the second mode in accordance with an application program as depicted in FIG. 6. The microprocessor 50, at block 90, determines whether a terminal mode command, indicating that the mode of the input device should change from the second mode to the first mode, has been received. If so, the microprocessor 50 proceeds to block 92 to operate the input device 10 in accordance with the first mode, without an application program as depicted in FIG. 5. If a terminal mode command indicating a change from the second mode to the first mode has not been received, the microprocessor 50 proceeds from block 90 to block 94 to determine whether a command in the application program or a command received by the input device is a command to send data to the printer. If so, the microprocessor 50 proceeds from block 94 to block 96 to send data to the printer 28. At block 98, the microprocessor implements an interpreter operation in which the processor 50 interprets each command of the application program. The processor 50 interprets a command by executing a command routine corresponding to the command. The corresponding command routines are executed in the order in which the commands are arranged in the application program.

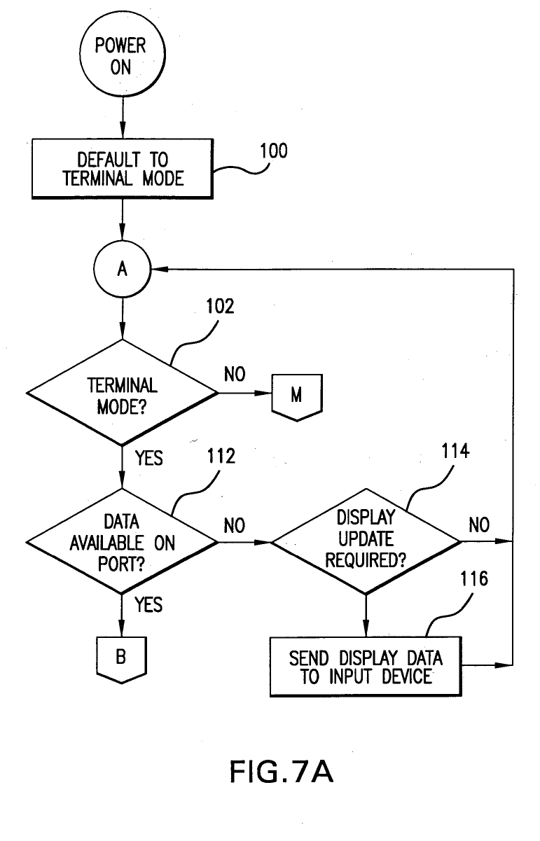

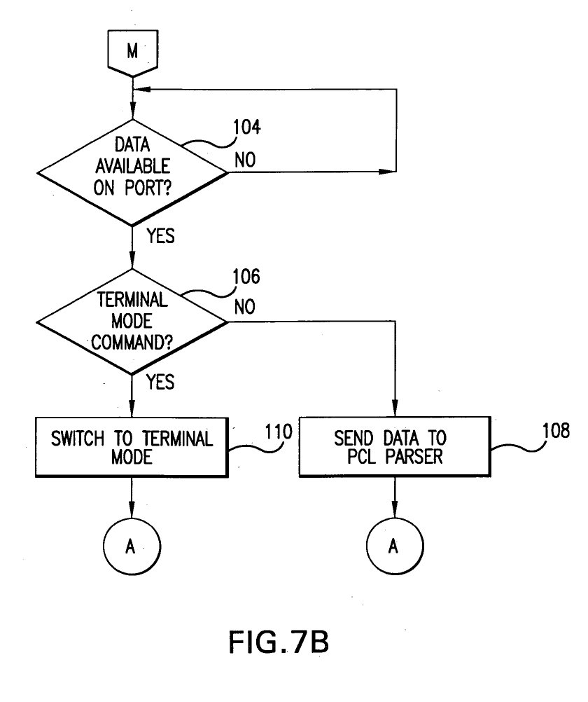

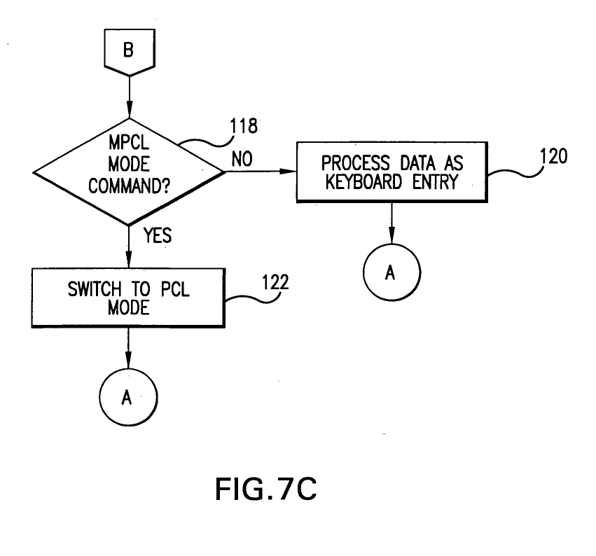

A printer 28 that is operable with or without an application program as shown in U.S. application Ser. No. 10/193,557 filed Jul. 11, 2002, assigned to the assignee of the present application and incorporated herein by reference is depicted in FIGS. 7A-C. When the printer 28 is turned on, the printer microprocessor at block 100 assumes that the input device 10 is operating in the first mode without an application program. At block 102, the printer microprocessor determines whether the input device is actually operating in the first mode, i.e. a terminal mode, without an application program and if not, the printer; microprocessor proceeds to the routine depicted in FIG. 7B. The routine depicted in FIG. 7B illustrates an operation of the printer 28 when the input device is operating in the second mode with an application program. At a block 104, the printer microprocessor determines whether data is available on a port and if so, the printer microprocessor proceeds to block 106. If the information on the port indicates that the input device has changed to the first mode via a terminal mode command, at block 106 the printer microprocessor switches to operate with an input device that is operating in the first mode, i.e. the terminal mode. If the information on the port indicates that the input device is still operating in the second mode, the printer microprocessor sends the data received from the input port to a printer control language parser at block 108 so that the printer can print the data received in the particular printer control language.

Returning to FIG. 7A, the printer microprocessor proceeds from block 102 to block 112 if the microprocessor determines that the input device is operating in the first mode or terminal mode, without an application program. At block 112, the printer microprocessor determines whether data is available on a port. If not, the printer microprocessor determines whether the display 16 of the input device needs to be updated at a block 114. If so, the printer microprocessor at block 116 sends display data to the input device 10 to which the input device 10 responds in the first mode by depicting information that represents the data on the display 16. In this way, the printer 28 can control an operation of the input device, i.e. the information depicted on a display. For example, the printer 28 can control the input device 10 to depict information on the display 16 to prompt a user to enter particular information that the printer needs for a print operation. If the printer microprocessor determines at block 112 that data is available on a port, the printer microprocessor proceeds from block 112 to block 118 depicted in FIG. 7C. At block 118, the printer microprocessor determines whether the information received on the port is a printer control language mode command to cause the printer 28 to operate in a particular mode. If not, the printer microprocessor proceeds from block 118 to block 120 to process the data as a data entry from the keyboard or scanner. If the printer microprocessor determines at block 118 that the information received on the port as determined at block 112 is a printer control language command, the printer microprocessor proceeds from block 118 to block 122 to switch to the mode indicated by the printer control language command.

The input device 10 of the present invention can operate in the first mode as a standard input device by passing data representing actuated keys or a sensed barcode in a standard ASCII format or the like to a printer without manipulating the data. Alternatively, the input device can operate as an intelligent input device that is capable of processing data, for example manipulating data to associate previously non-associated data inputs and/or to provide data collection capabilities so as to gather data together in a file, look up table, array or the like. The flexibility of the input device 10 of the present invention allows a single input device to be used with printers that are themselves intelligent and/or non-intelligent, i.e. printers that are merely output devices that print data received in a particular printer control language format.

Many modifications and variations of the present invention are possible in light of the above teachings. Thus, it is to be understood that, within the scope of the appended claims, the invention may be practiced otherwise than as described hereinabove.

1. An input device for a printer, the input device being operable in at least two modes and comprising:
a housing;
a plurality of keys on a surface of the housing;
a display;
at least one communication interface for receiving data and transmitting data to a printer;
at least one memory for storing an application program that includes a sequence of commands, the at least one memory storing one or more routines to control the operation of the input device without an application program and a plurality of routines each of which corresponds to a command that can be included in an application program; and
a processor for operating the input device in a first mode according to the routines that control the operation without an application program and for operating the input device in a second mode according to the application program, the processor in the second mode executing the routines corresponding to the commands in the application program.

2. An input device as recited in claim 1 wherein the processor is responsive to a command while the input device is in a second mode to change the mode to the first mode.

3. An input device as recited in claim 1 wherein the input device in the first mode passes to the printer data representing actuated keys.

4. An input device as recited in claim 1 a second communication interface for connection to a barcode scanner, the input device in the first mode passes to the printer data representing actuated keys and/or data from the barcode scanner.

5. An input device as recited in claim 1 wherein the input device in the first mode depicts information received from the printer on the display, the information providing a prompt to a user to enter data and the input device passing entered data to the printer.

6. An input device as recited in claim 5 a second communication interface for connection to a barcode scanner, the input device in the first mode passes to the printer data representing actuated keys and/or data from the barcode scanner.

7. An input device as recited in claim 1 wherein the routines corresponding to application program commands include one or more routines for collecting data by gathering previously non-associated data together in a file or array.

8. An input device as recited in claim 1 wherein the routines corresponding to application program commands include one or more routines for manipulating data including a routine to associate previously non-associated data.

9. An input device as recited in claim 1 wherein the processor in the second mode depicts information, determined by an application program, on the display of the input device.

10. An input device as recited in claim 1 wherein the processor operates in the second mode to provide to the printer a print control command and a stream of data having a predetermined format.

11. An input device as recited in claim 10 wherein the processor operates in the first mode to pass to the printer data corresponding to actuated keys in the order in which the corresponding keys are actuated.

12. An input device as recited in claim 1 wherein the routines controlling the operation of the input device without an application program and the routines corresponding to an application program commands are programmable to allow the input device to be updated but not by a user and wherein the application program is programmable by the user to change the commands of an application program and/or to change the order of execution of the commands.

13. An input device as recited in claim 1 wherein the input device in the first mode is controlled at least in part by inputs received from a printer and wherein the input device in the second mode controls at least in part an operation of the printer.

14. An input device as recited in claim 1 wherein the input device receives power from a printer.

15. An input device as recited in claim 1 wherein the communication interface is a port through which power is supplied from the printer.

16. An input device as recited in claim 1 wherein the keys include programmable function keys.

17. An input device as recited in claim 1 wherein the keys include alpha-numeric keys.

18. An input device as recited in claim 1 wherein the keys include one or more cursor control keys.

19. An input device as recited in claim 1 wherein the keys include one or more printer control keys.

20. An input device as recited in claim 19 wherein the printer control keys include a feed key to generate a feed command for a printer to cause the printer to advance printing stock through the printer.

21. An input device as recited in claim 19 wherein the printer control keys include a pause key to generate a pause command for a printer to cause the printer to pause the printer's operation.

22. An input device as recited in claim 19 wherein the printer control keys include a cut key to generate a cut command for a printer to cause the printer to cut the printing stock.

23. An input device for a printer, the input device being operable in at least two modes and comprising:
a housing;
a plurality of keys on a surface of the housing;
a display;
at least one communication interface for receiving data and transmitting data to a printer and for receiving power from the printer to power the input device;
at least one memory for storing an application program; and
a processor for operating the input device in a first mode to control the operation of the input device without an application program to pass data representing actuated keys to the communication interface for the printer and for operating the input device in a second mode to control the operation of the input device in accordance with an application program.

24. An input device as recited in claim 23 wherein the input device when operating in the second mode generates data streams in a predetermined printer control language for communication to a printer via the communication interface.

25. An input device as recited in claim 23 wherein the input device when operating in the second mode generates printer commands in a predetermined printer control language.

26. An input device as recited in claim 23 including a communication interface for a barcode scanner.

27. An input device as recited in claim 26 wherein the communication interface passes power from the input device to the barcode scanner.

28. An input device as recited in claim 23 wherein the input device in the first mode is controlled at least in part by inputs received from a printer and wherein the input device in the second mode controls at least in part an operation of the printer.

29. An input device as recited in claim 23 wherein the keys include programmable function keys.

30. An input device as recited in claim 23 wherein the keys include alpha-numeric keys.

31. An input device as recited in claim 23 wherein the keys include one or more cursor control keys.

32. An input device as recited in claim 23 wherein the keys include one or more printer control keys.

33. An input device as recited in claim 32 wherein the printer control keys include a feed key to generate a feed command for a printer to cause the printer to advance printing stock through the printer.

34. An input device as recited in claim 32 wherein the printer control keys include a pause key to generate a pause command for a printer to cause the printer to pause the printer's operation.

35. An input device as recited in claim 32 wherein the printer control keys include a cut key to generate a cut command for a printer to cause the printer to cut the printing stock.

36. An input device for a printer, the input device being operable in at least two modes and comprising:
a housing;
a plurality of keys on a surface of the housing;
a display;
at least one communication interface for receiving data and transmitting data to a printer; and
a processor for operating the input device in a first mode wherein the input device is responsive to information received from the printer to control an operation of the input device and for operating the input device in a second mode wherein the input device controls an operation of the printer.

37. An input device for a printer, the input device being operable in at least two modes and comprising:
a housing;
a plurality of keys on a surface of the housing;
a display;
at least one communication interface for receiving data and transmitting data to a printer; and
a processor for operating the input device in a non-intelligent mode wherein the input device passes data, representing a user input, to the printer without manipulating the data and for operating the input device in an intelligent mode wherein the input device can manipulate data to output the data in a predetermined format to the printer.

38. An input device as recited in claim 37 wherein the keys include programmable function keys.

39. An input device as recited in claim 37 wherein the keys include alpha-numeric keys.

40. An input device as recited in claim 37 wherein the keys include one or more cursor control keys.

41. An input device as recited in claim 37 wherein the keys include one or more printer control keys.

42. An input device as recited in claim 41 wherein the printer control keys include a feed key to generate a feed command for a printer to cause the printer to advance printing stock through the printer.

43. An input device as recited in claim 41 wherein the printer control keys include a pause key to generate a pause command for a printer to cause the printer to pause the printer's operation.

44. An input device as recited in claim 41 wherein the printer control keys include a cut key to generate a cut command for a printer to cause the printer to cut the printing stock.
